(19) United States
(12) Patent Application Publication
(10) Pub. No.: US 2021/0180175 A1
(43) Pub. Date: Jun. 17, 2021

(54) METHOD FOR PREPARING BACTERICIDAL FILM HAVING TITANIUM CARBONITRIDE CARRIER LAYER ON METAL

(71) Applicant: Fook Chi MAK, Hong Kong (CN)

(72) Inventor: Fook Chi MAK, Hong Kong (CN)

(21) Appl. No.: 16/903,925

(22) Filed: Jun. 17, 2020

(30) Foreign Application Priority Data
Dec. 17, 2019 (CN) 2019113039303

(51) Int. Cl. C23C 14/06; C23C 14/34; C23C 14/02; A01N 25/08

(52) U.S. Cl. CPC C23C 14/0664; A01N 25/08; C23C 14/021; C23C 14/3414

(57) ABSTRACT

A method for preparing a bactericidal film having a titanium carbonitride carrier layer on metal comprising preprocessing, polishing, plating a bactericidal film carrier layer and a bactericidal film. The surface of the polished metal is smooth. During the plating process, as silver ions do not react with carbon and nitrogen, through changing the number of carbon and nitrogen atoms, various desired colors of the bactericidal film may be achieved. Subsequently, a nano silver sputtering target is initiated, which enables silver ions with bactericidal effect to be uniformly distributed in the titanium carbonitride film layer, thus forming a colored bactericidal film with bactericidal effect. The workpiece is hung on the hanging rack during the plating process, which allows the rotation and revolution of the workpiece to be simultaneously achieved, thus realizing a uniform plating during the target's sputtering while avoiding damage to the workpiece due to local high temperature.

### TECHNICAL FIELD

This disclosure generally relates to the technical field of manufacturing bactericidal films, and more particularly, to a method for preparing a bactericidal film having a titanium carbonitride carrier layer on metal.

### BACKGROUND

Metal products are widely used in our daily lives for their possessing good texture, smooth lines, and elegant luster. Many of them, such as home decoration materials, home-used products, and mobile phone shells, are frequently used and in direct contact with people. These metal products inevitably carry a large number of bacteria. Scientific research shows that the bacteria carried on a mobile phone used every day is much more than that on a flushing toilet. Thus, a method capable of protecting metal products from bacteria is particularly wanted.

With the improvement of living standard, people are demanding high quality metal products. Other than a bactericidal ability, various colors and patterns of the metal products are also demanded.

### SUMMARY

The purpose of the present disclosure is to provide a method for preparing a bactericidal film having a titanium carbonitride carrier layer on metal.

To achieve the above purpose, the present disclosure adopts the following technical solution: A method for preparing a bactericidal film having a titanium carbonitride carrier layer on metal, comprising: removing the oil from a workpiece and cleansing the workpiece; placing the workpiece in an acidic solution for chemical polishing; processing the workpiece with a vacuum furnace, wherein processing the workpieces with the vacuum furnace includes: hanging the preprocessed workpiece on a hanging rack, and placing the hanging rack into the vacuum furnace, supplying a bias voltage to the hanging rack to increase voltage to 700V and vacuuming the vacuum furnace to a vacuum degree of 0.5-1.5×10-3 Pa, and initiating a rotating disc to make the workpiece rotates on the hanging rack and simultaneously make the hanging rack rotate within the vacuum furnace; removing oxidation film on the workpiece by introducing argon to enable argon ions to bombard a surface of the workpiece; plating a bactericidal film interface layer on the workpiece, wherein plating the bactericidal film interface layer includes: reducing the bias voltage, switching on a power supply and regulating the voltage to 30-40V, wherein a duty ratio is configured to control the power supply, wherein the duty ratio is between 20% to 30%; enabling the vacuum degree to reach 0.3-1 Pa by continuously introducing the argon; forming a pure titanium film layer on the surface of the workpiece by initiating a titanium sputtering target and keeping the titanium sputtering target sputtering for 3 minutes to 4 minutes; preliminarily plating a bactericidal film carrier layer, wherein preliminarily plating the bactericidal film carrier layer includes forming a titanium nitride film layer on the workpiece by keeping the titanium sputtering target sputtering and introducing nitrogen; completing the plating of the bactericidal film carrier layer, wherein completing the plating of the bactericidal film carrier layer includes: keeping the titanium sputtering target sputtering and continuously introducing nitrogen, and forming a titanium carbonitride bactericidal film carrier layer on the surface of the workpiece by introducing the argon at a first flow rate and introducing acetylene gas; plating the bactericidal film, wherein plating the bactericidal film includes forming a silver bactericidal film layer on the surface of the workpiece by initiating a silver sputtering target; and completing the plating of the bactericidal film, wherein completing the plating of the bactericidal film includes: stopping the titanium sputtering target and turning off the nitrogen, turning off the acetylene gas, stopping the silver sputtering target, and turning off gases, air-extracting for 5 minutes to 10 minutes to remove residual carbon ions in the vacuum furnace, releasing the vacuum furnace until pressure in the vacuum furnace and atmospheric pressure are balanced, and taking out the workpiece.

In another preferred embodiment, the color of the bactericidal film varies along with the variation of the number of nitrogen atoms.

In another preferred embodiment, the color of the bactericidal film varies along with the variation of the number of carbon atoms.

In another preferred embodiment, the acidic solution is a nitric acid solution.

In another preferred embodiment, the workpiece is an aluminum workpiece, an aluminum-alloy workpiece, a magnesium-alloy workpiece, a stainless-steel workpiece, or other metal workpieces.

In another preferred embodiment, the bias voltage supplied to the hanging rack is between −40V to −300V.

In another preferred embodiment, preliminarily plating the bactericidal film carrier layer further includes: introducing the argon at a second flow rate, wherein the second flow rate is between 100-250 sccm, supplying a current to the titanium sputtering target, wherein the current is 10 A, and electroplating the bactericidal film carrier layer between 2 minutes to 10 minutes.

In another preferred embodiment, the first flow rate is between 40 sccm to 80 sccm, wherein the acetylene gas is introduced at a third flow rate between 150 sccm to 250 sccm and has an introduction duration between 1 minute to 5 minutes.

In another preferred embodiment, plating the bactericidal film further includes: supplying a current to the silver sputtering target, wherein the current is between 0.5 A to 1 A, and sputtering the sliver sputtering target between 1 minute to 4 minutes.

The method for preparing a bactericidal film having a titanium carbonitride carrier layer on metal of the present disclosure includes preprocessing, polishing, plating a bactericidal film carrier layer and plating a bactericidal film. The whole process does not need high temperature, and the film layers are plated without damaging the metal workpiece. After forming a titanium nitride carrier layer using a titanium target and nitrogen, acetylene gas is introduced to form a titanium carbonitride carrier layer. The surface of the polished metal is smooth. During the plating process, as silver ions do not react with carbon and nitrogen, through changing the number of carbon and nitrogen atoms, various desired colors of the bactericidal film carrier layer may be achieved according to actual needs. Subsequently, a nano silver sputtering target is initiated, which enables silver ions with bactericidal effect to be uniformly distributed in the titanium carbonitride film layer, thus forming a colored bactericidal film with bactericidal effect.

### DETAILED DESCRIPTION

To make the purpose, technical solution and advantages of the present disclosure clearer, detailed embodiments are combined hereinafter to further elaborate the techniques of the present disclosure. It should be understood that the described embodiments are merely used for better understanding the technical solution of the present disclosure but not limiting the present disclosure.

A method for preparing a bactericidal film having a titanium carbonitride carrier layer on metal, comprising the steps of:

Preprocessing: removing the oil from a workpiece and cleansing the workpiece.

Polishing: placing the cleansed workpiece in an acidic solution for chemical polishing.

Vacuum processing: hanging the preprocessed workpiece on a hanging rack, and placing into a vacuum furnace; supplying a bias voltage to the metal hanging rack to increase the voltage to 700V, and vacuuming the furnace to a vacuum degree of 0.5-1.5×10⁻³ Pa; initiating a rotating disc, thus making the workpiece rotate on the hanging rack, and simultaneously making the hanging rack rotate within the vacuum furnace.

Ion cleaning: introducing argon to enable argon ions to bombard the surface of the workpiece, thereby removing the oxidation film on the workpiece;

Plating a bactericidal film interface layer: reducing the bias voltage, switching on a power supply and regulating the voltage to 30-40V, wherein the duty ratio is 20-30%; continuously introducing argon, thereby enabling the vacuum degree to reach 0.3-1 Pa; subsequently, initiating a titanium sputtering target and keeping the titanium target sputtering for 3-4 minutes, thereby forming a pure titanium film layer on the surface of the workpiece.

Preliminarily plating a bactericidal film carrier layer: keeping the titanium target sputtering and introducing nitrogen, thereby forming a titanium nitride film layer on the workpiece.

Completing the plating of the bactericidal film carrier layer: keeping the titanium target sputtering and continuously introducing nitrogen; reducing the flow of argon, and introducing acetylene gas, thus forming a titanium carbonitride bactericidal film carrier layer on the surface of the workpiece.

Plating a bactericidal film: initiating a silver sputtering target, thus forming a silver bactericidal film layer on the surface of the workpiece.

Completing the plating of the bactericidal film: stopping the titanium target and turning off the nitrogen; subsequently, turning off the acetylene gas and stopping the silver target, and then turning off all the gases; air-extracting for 5-10 minutes to remove the residual carbon ions in the vacuum furnace; releasing the vacuum furnace until the pressure in the furnace and the atmospheric pressure are balanced; finally, taking out the workpiece, thereby completing the whole plating process.

In one of the embodiments, in step (6), the color of the bactericidal film varies along with the variation of the number of nitrogen atoms.

In one of the embodiments, in step (7), the color of the bactericidal film varies along with the variation of the number of carbon atoms.

In one of the embodiments, in step (2), the chemical polishing agent is a nitric acid solution.

In one of the embodiments, the workpiece is an aluminum workpiece, an aluminum-alloy workpiece, a magnesium-alloy workpiece, a stainless-steel workpiece, or other metal workpieces.

In one of the embodiments, the bias voltage supplied to the metal hanging rack in step (2) is −40-−300V.

In one of the embodiments, in step (6), the flow rate of argon is 100-250 sccm, the current supplied to the target material is 10 A, and the electroplating duration is 2-10 minutes.

In one of the embodiments, in step (7), the flow rate of argon is reduced to 40-80 sccm, the flow rate of acetylene gas is 150-250 sccm, and the introduction duration of acetylene gas is 1-5 minutes.

In one of the embodiments, in step (8), the current supplied to the silver target is 0.5-1 A, and the sputtering duration of the sliver target is 1-4 minutes.

### Embodiment 1

A method for preparing a bactericidal film having a titanium carbonitride carrier layer on metal, comprising the steps of:

Preprocessing: removing the oil from a workpiece and cleansing the workpiece.

Polishing: placing the cleansed workpiece in an acidic solution for chemical polishing.

Vacuum processing: hanging the preprocessed workpiece on a hanging rack, and placing into a vacuum furnace; supplying a bias voltage to the metal hanging rack to increase the voltage to 700V, and vacuuming the furnace to a vacuum degree of 0.5-1.5×10⁻³ Pa; initiating a rotating disc, thus making the workpiece rotate on the hanging rack, and simultaneously making the hanging rack rotate within the vacuum furnace.

Ion cleaning: introducing argon to enable argon ions to bombard the surface of the workpiece, thereby removing the oxidation film on the workpiece.

Plating a bactericidal film interface layer: reducing the bias voltage, switching on a power supply and regulating the voltage to 30-40V, wherein the duty ratio is 20-30%; continuously introducing argon, thereby enabling the vacuum degree to reach 0.3-1 Pa; subsequently, initiating a titanium sputtering target and keeping the titanium target sputtering for 3-4 minutes, thereby forming a pure titanium film layer on the surface of the workpiece.

Preliminarily plating a bactericidal film carrier layer: keeping the titanium target sputtering and introducing nitrogen, thereby forming a titanium nitride film layer on the workpiece.

Completing the plating of the bactericidal film carrier layer: keeping the titanium target sputtering and continuously introducing nitrogen; reducing the flow of argon, and introducing acetylene gas, thus forming a titanium carbonitride bactericidal film carrier layer on the surface of the workpiece.

Plating a bactericidal film: initiating a silver sputtering target, thus forming a silver bactericidal film layer on the surface of the workpiece.

Completing the plating of the bactericidal film: stopping the titanium target and turning off the nitrogen; subsequently, turning off the acetylene gas and stopping the silver target, and then turning off all the gases; air-extracting for 5 minutes to remove the residual carbon ions in the vacuum furnace; releasing the vacuum furnace until the pressure in the furnace and the atmospheric pressure are balanced; finally, taking out the workpiece, thereby completing the whole plating process.

### Embodiment 2

The method for preparing a bactericidal film having a titanium carbonitride carrier layer on metal, comprising the steps of:

Preprocessing: removing the oil from a workpiece and cleansing the workpiece.

Polishing: placing the cleansed workpiece in an acidic solution for chemical polishing.

Vacuum processing: hanging the preprocessed workpiece on a hanging rack, and placing into a vacuum furnace; supplying a bias voltage to the metal hanging rack to increase the voltage to 700V, and vacuuming the furnace to a vacuum degree of 0.5-1.5×10⁻³ Pa; initiating a rotating disc, thus making the workpiece rotate on the hanging rack, and simultaneously making the hanging rack rotate within the vacuum furnace.

Ion cleaning: introducing argon to enable argon ions to bombard the surface of the workpiece, thereby removing the oxidation film on the workpiece;

Plating a bactericidal film interface layer: reducing the bias voltage, switching on a power supply and regulating the voltage to 30-40V, wherein the duty ratio is 20-30%; continuously introducing argon, thereby enabling the vacuum degree to reach 0.3-1 Pa; subsequently, initiating a titanium sputtering target and keeping the titanium target sputtering for 3-4 minutes, thereby forming a pure titanium film layer on the surface of the workpiece.

Preliminarily plating a bactericidal film carrier layer: keeping the titanium target sputtering and introducing nitrogen, thereby forming a titanium nitride film layer on the workpiece.

Completing the plating of the bactericidal film carrier layer: keeping the titanium target sputtering and continuously introducing nitrogen; reducing the flow of argon, and introducing acetylene gas, thus forming a titanium carbonitride bactericidal film carrier layer on the surface of the workpiece.

Plating a bactericidal film: initiating a silver sputtering target, thus forming a silver bactericidal film layer on the surface of the workpiece.

Completing the plating of the bactericidal film: stopping the titanium target and turning off the nitrogen; subsequently, turning off the acetylene gas and stopping the silver target, and then turning off all the gases; air-extracting for 8 minutes to remove the residual carbon ions in the vacuum furnace; releasing the vacuum furnace until the pressure in the furnace and the atmospheric pressure are balanced; finally, taking out the workpiece, thereby completing the whole plating process.

### Embodiment 3

The method for preparing a bactericidal film having a titanium carbonitride carrier layer on metal, comprising the steps of:

Preprocessing: removing the oil from a workpiece and cleansing the workpiece.

Polishing: placing the cleansed workpiece in an acidic solution for chemical polishing.

Vacuum processing: hanging the preprocessed workpiece on a hanging rack, and placing into a vacuum furnace; supplying a bias voltage to the metal hanging rack to increase the voltage to 700V, and vacuuming the furnace to a vacuum degree of 0.5-1.5×10⁻³ Pa; initiating a rotating disc, thus making the workpiece rotate on the hanging rack, and simultaneously making the hanging rack rotate within the vacuum furnace.

Ion cleaning: introducing argon to enable argon ions to bombard the surface of the workpiece, thereby removing the oxidation film on the workpiece.

Plating a bactericidal film interface layer: reducing the bias voltage, switching on a power supply and regulating the voltage to 30-40V, wherein the duty ratio is 20-30%; continuously introducing argon, thereby enabling the vacuum degree to reach 0.3-1 Pa; subsequently, initiating a titanium sputtering target and keeping the titanium target sputtering for 3-4 minutes, thereby forming a pure titanium film layer on the surface of the workpiece.

Preliminarily plating a bactericidal film carrier layer: keeping the titanium target sputtering and introducing nitrogen, thereby forming a titanium nitride film layer on the workpiece.

Completing the plating of the bactericidal film carrier layer: keeping the titanium target sputtering and continuously introducing nitrogen; reducing the flow of argon, and introducing acetylene gas, thus forming a titanium carbonitride bactericidal film carrier layer on the surface of the workpiece.

Plating a bactericidal film: initiating a silver sputtering target, thus forming a silver bactericidal film layer on the surface of the workpiece.

Completing the plating of the bactericidal film: stopping the titanium target and turning off the nitrogen; subsequently, turning off the acetylene gas and stopping the silver target, and then turning off all the gases; air-extracting for 5-10 minutes to remove the residual carbon ions in the vacuum furnace; releasing the vacuum furnace until the pressure in the furnace and the atmospheric pressure are balanced; finally, taking out the workpiece, thereby completing the whole plating process.

### Embodiment 4

After respectively measuring the film layer binding force of the bactericidal film having a titanium carbonitride carrier layer on each of the metal workpieces obtained from the aforesaid embodiments 1-3, the measurement results are shown in the following table:

| Embodiment | 1 | 2 | 3 |
|---|---|---|---|
| Binding Force (N) | 62 | 63.8 | 65 |

From the above results, it can be seen that, the film layer binding force of the bactericidal film on each of the metal workpieces obtained through adopting the techniques of the present disclosure is greater than 60 N, which indicates that the film layer binding force is strong enough to meet the requirements of ordinary metal products.

### Embodiment 5

The metal workpieces obtained from embodiments 1-3 are all mobile phone shells made of an aluminum-alloy, which are respectively numbered as groups 1-3, and a conventional mobile phone shell made of the same material is taken as a comparison group. The number of bacterial colonies on the surface of the four groups of samples is respectively observed after 6 and 12 hours under the same using condition. The results are shown in the following table:

| | | | | Comparison |
|---|---|---|---|---|
| Samples | Group 1 | Group 2 | Group 3 | Group |
| 6 hours | 25 | 23 | 25 | 38 |
| (number/cm²) | | | | |
| 12 hours | 30 | 26 | 29 | 49 |
| (number/cm²) | | | | |

From the above results, it can be seen that, compared with conventional aluminum-alloy mobile phone shells, mobile phone shells plated with the bactericidal film having a titanium carbonitride carrier layer of the present disclosure achieves a significant bactericidal effect and thus possesses a high practical value.

The above is merely a description of preferred embodiments of the present disclosure, which cannot be understood as a limitation of the claims. Any equivalent modifications of the structure or process described in the specification of the present disclosure shall fall into the scope of the present disclosure.

What is claimed is:

1. A method for preparing a bactericidal film having a titanium carbonitride carrier layer on metal, comprising:
removing the oil from a workpiece and cleansing the workpiece;
placing the workpiece in an acidic solution for chemical polishing;
processing the workpiece with a vacuum furnace, wherein processing the workpieces with the vacuum furnace comprises:
hanging the preprocessed workpiece on a hanging rack and placing the hanging rack into the vacuum furnace,
supplying a bias voltage to the hanging rack to increase voltage to 700V and vacuuming the vacuum furnace to a vacuum degree of 0.5-1.5×10⁻³ Pa, and
initiating a rotating disc to make the workpiece rotates on the hanging rack and simultaneously make the hanging rack rotates within the vacuum furnace;
removing oxidation film on the workpiece by introducing argon to enable argon ions to bombard a surface of the workpiece;
plating a bactericidal film interface layer on the workpiece, wherein plating the bactericidal film interface layer comprises:
reducing the bias voltage, switching on a power supply and regulating the voltage to 30-40V, wherein a duty ratio is configured to control the power supply, wherein the duty ratio is between 20% to 30%,
enabling the vacuum degree to reach 0.3-1 Pa by continuously introducing the argon, and
forming a pure titanium film layer on the surface of the workpiece by initiating a titanium sputtering target and keeping the titanium sputtering target sputtering for 3 minutes to 4 minutes;
preliminarily plating a bactericidal film carrier layer, wherein preliminarily plating the bactericidal film carrier layer comprises forming a titanium nitride film layer on the workpiece by keeping the titanium sputtering target sputtering and introducing nitrogen;
completing the plating of the bactericidal film carrier layer, wherein completing the plating of the bactericidal film carrier layer comprises:
keeping the titanium sputtering target sputtering and continuously introducing nitrogen, and
forming a titanium carbonitride bactericidal film carrier layer on the surface of the workpiece by introducing the argon at a first flow rate and introducing acetylene gas;
plating the bactericidal film, wherein plating the bactericidal film comprises forming a silver bactericidal film layer on the surface of the workpiece by initiating a silver sputtering target; and
completing the plating of the bactericidal film, wherein completing the plating of the bactericidal film comprises:
stopping the titanium sputtering target and turning off the nitrogen,
turning off the acetylene gas, stopping the silver sputtering target, and turning off gases,
air-extracting for 5 minutes to 10 minutes to remove residual carbon ions in the vacuum furnace,
releasing the vacuum furnace until pressure in the vacuum furnace and atmospheric pressure are balanced, and
taking out the workpiece.

2. The method for preparing a bactericidal film having a titanium carbonitride carrier layer on metal of claim 1, wherein color of the bactericidal film varies along with the variation of the number of nitrogen atoms.

3. The method for preparing a bactericidal film having a titanium carbonitride carrier layer on metal of claim 1, wherein color of the bactericidal film varies along with the variation of the number of carbon atoms.

4. The method for preparing a bactericidal film having a titanium carbonitride carrier layer on metal of claim 1, wherein the acidic solution is a nitric acid solution.

5. The method for preparing a bactericidal film having a titanium carbonitride carrier layer on metal of claims 1, wherein the workpiece is an aluminum workpiece, an aluminum-alloy workpiece, a magnesium-alloy workpiece, a stainless-steel workpiece, or other metal workpieces.

6. The method for preparing a bactericidal film having a titanium carbonitride carrier layer on metal of claim 1, wherein the bias voltage supplied to the hanging rack is between −40V to −300V.

7. The method for preparing a bactericidal film having a titanium carbonitride carrier layer on metal of claim 1, wherein preliminarily plating the bactericidal film carrier layer further comprises:
introducing the argon at a second flow rate, wherein the second flow rate is between 100-250 sccm,
supplying a current to the titanium sputtering target, wherein the current is 10 A, and
electroplating the bactericidal film carrier layer between 2 minutes to 10 minutes.

8. The method for preparing a bactericidal film having a titanium carbonitride carrier layer on metal of claim 1, wherein the first flow rate is between 40 sccm to 80 sccm, wherein the acetylene gas is introduced at a third flow rate between 150 sccm to 250 sccm and has an introduction duration between 1 minute to 5 minutes.

9. The method for preparing a bactericidal film having a titanium carbonitride carrier layer on metal of claim 1, wherein plating the bactericidal film further comprises:
supplying a current to the silver sputtering target, wherein the current is between 0.5 A to 1 A, and
sputtering the sliver sputtering target between 1 minute to 4 minutes.
